(19) United States
(12) Patent Application Publication
(10) Pub. No.: US 2025/0219603 A1
(43) Pub. Date: Jul. 3, 2025

(54) AMPLIFYING CIRCUIT AND AMPLIFYING DEVICE

(71) Applicant: SAMSUNG ELECTRONICS CO., LTD., SUWON-SI (KR)

(72) Inventor: JIHUN LEE, SUWON-SI (KR)

(21) Appl. No.: 19/000,848

(22) Filed: Dec. 24, 2024

(30) Foreign Application Priority Data
Dec. 29, 2023 (KR) 10-2023-0197646
Mar. 13, 2024 (KR) 10-2024-0035473

(51) Int. Cl. H03F 3/45; H03F 3/217

(52) U.S. Cl. CPC H03F 3/45183; H03F 3/45636; H03F 3/2173; H03F 2200/03; H03F 2200/372

(57) ABSTRACT

An amplifying circuit, which includes a first power stage circuit that outputs a first output signal to a first node based on a pull-up or a pull-down, a second power stage circuit that outputs a second output signal to a second node based on the pull-up or the pull-down, a current path switch connected to the first node and the second node, and that is turned on when the first power stage circuit and the second power stage circuit are turned off, and a voltage supply circuit that supplies a common mode voltage for the first output signal and the second output signal to the first node and the second node when the first power stage circuit and the second power stage circuit are turned off.

### CROSS-REFERENCE TO RELATED APPLICATIONS

This US patent application claims priority under 35 U.S.C. § 119 to Korean Patent Application Nos. 10-2023-0197646 filed on Dec. 29, 2023, and 10-2024-0035473 filed on Mar. 13, 2024, respectively, in the Korean Intellectual Property Office, the disclosures of which are incorporated by reference in their entireties herein.

### 1. TECHNICAL FIELD

Embodiments of the present disclosure described herein are directed to an amplifying circuit and an amplifying device.

### 2. DISCUSSION OF RELATED ART

Class-AB amplifiers have been mainly used to reproduce sound in wired devices such as wired earphones, wired headphones, personal computers and stereos. While Class A-B amplifiers are known for their sound quality, they are less efficient than Class-D amplifiers, typically offering around 50-70% efficiency. They produce more heat and consume more power, which makes them less suitable for battery-powered devices like True Wireless Stereo (TWS) earphones.

Mobile devices, such as wireless earphones, wireless headphones and smartphones, may be required to have longer battery times by reducing standby power consumption or increasing power efficiency. Thus, Class-D amplifiers may be used in such devices.

However, electromagnetic interference (EMI) occurs in class-D amplifiers due to fluctuations in common mode voltage depending on modulation methods. These fluctuations can lead to noise being introduced into the output signal, which may affect audio quality,

### SUMMARY

Embodiments of the present disclosure provide an amplifying circuit and an amplifying device capable of uniformly providing a common mode voltage to reduce or eliminate noise.

According to an embodiment of the present disclosure, an amplifying circuit includes a first power stage circuit, a second power stage circuit, a current path switch and a voltage supply circuit. The first power stage circuit outputs a first output signal to a first node based on a pull-up or a pull-down. The second power stage circuit outputs a second output signal to a second node based on the pull-up or the pull-down. The current path switch is connected to the first node and the second node, and is turned on when the first power stage circuit and the second power stage circuit are turned off. The voltage supply circuit supplies a common mode voltage for the first output signal and the second output signal to the first node and the second node when the first power stage circuit and the second power stage circuit are turned off.

According to an embodiment of the present disclosure, an amplifying circuit includes a first inverter, a second inverter, a first transistor, a second transistor and a third transistor. The first inverter outputs a first output signal to a first node based on a pull-up or a pull-down. The second inverter outputs a second output signal to a second node based on the pull-up or the pull-down. The first transistor is connected between the first node and the second node and is turned on based when the first inverter and the second inverter are turned off. The second transistor is connected between the first node a common mode voltage, and is turned on when the first inverter and the second inverter are turned off. The third transistor is connected to the second node and the common mode voltage, and is turned on when the first inverter and the second inverter are turned off.

According to an embodiment of the present disclosure, an amplifying device includes a pair of current digital-to-analog converters (DACs), a pair of amplifying channels, a current switch, and a voltage supply circuit. The pair of DACs converts data differential input signals to analog differential signals. The pair of amplifying channels are connected to the pair of current DACs, and generate differential pulse signals from the analog differential input signals, a common mode signal, and differential triangle wave signals, and outputs differential output signals corresponding to the differential pulse signals through a pair of power stage circuits. The current path switch is connected to a first node and a second node through which the differential output signals are output, and is turned on when the pair of power stage circuits are turned off. The voltage supply circuit supplies a common mode voltage with respect to the differential output signals to the first node and the second node when the pair of power stage circuits are turned off.

### BRIEF DESCRIPTION OF THE FIGURES

The above and other objects and features of the present disclosure will become apparent by describing in detail embodiments thereof with reference to the accompanying drawings.

FIG. 1 illustrates an amplifying circuit, according to an embodiment.

FIG. 2 is a circuit diagram of a voltage supply circuit, according to an embodiment.

FIG. 3 is a circuit diagram of an amplifying circuit, according to an embodiment.

FIG. 4 illustrates an operation of an amplifying circuit in a first mode, according to an embodiment, and FIG. 5 illustrates an operation of an amplifying circuit in a second mode, according to an embodiments.

FIG. 6 illustrates an amplifying device, according to an embodiment.

FIGS. 7 and 8 illustrate operating waveforms of an amplifying device of FIG. 6, according to an embodiment.

FIG. 9 is a flowchart illustrating a method of operating an amplifying device, according to an embodiment.

FIG. 10 illustrates an audio device, according to an embodiment.

### DETAILED DESCRIPTION

Hereinafter, embodiments of the present disclosure will be described in detail and clearly to such an extent that an one of ordinary skill in the art may implement the present disclosure.

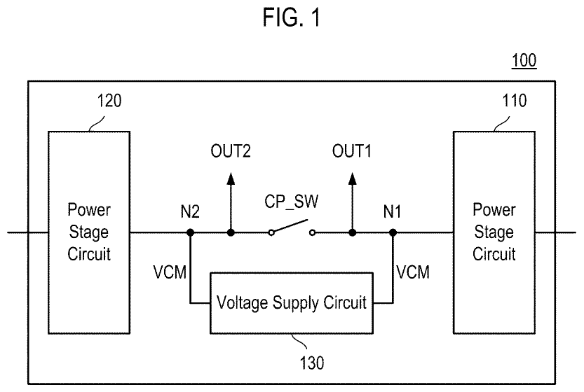

FIG. 1 illustrates an amplifying circuit, according to an embodiment.

Referring to FIG. 1, an amplifying circuit 100 according to an embodiment includes a first power stage circuit 110, a second power stage circuit 120, a current path switch CP_SW, and a voltage supply circuit 130.

The first power stage circuit 110 is connected to a first node N1 and may be configured to output a first output signal OUT1 to the first node N1. The second power stage circuit 120 is connected to a second node N2 and may be configured to output a second output signal OUT2 to the second node N2. The first power stage circuit 110 and the second power stage circuit 120 may output the first output signal OUT1 and the second output signal OUT2 based on a pull-up or a pull-down. For the pull-up or the pull-down, the first power stage circuit 110 and the second power stage circuit 120 may be configured to include one or more pull-up switches and one or more pull-down switches.

In an embodiment, the first output signal OUT1 and the second output signal OUT2 are differential signals having different phases. The first power stage circuit 110 and the second power stage circuit 120 may perform the pull-up or the pull-down based on a pulse signal, which has a duty cycle proportional to a level of differential input signals corresponding to differential output signals. Each power stage circuit may operate based on pulse signals corresponding to input signals of different phases.

In an embodiment, a load is connected to the first node N1 and the second node N2 through which the first output signal OUT1 and the second output signal OUT2 are output. In this embodiment, the amplifying circuit 100 may be considered as having a bridge tied load (BTL) form (or a full-bridge form or an H-bridge form) in which the first power stage circuit 110 and the second power stage circuit 120 form a bridge with the load. Each power stage circuit (e.g., 110 and 120) may be considered as a half-bridge. An effective output signal corresponding to a difference between the first output signal OUT1 and the second output signal OUT2, which are the differential output signals, appears at the load.

According to an embodiment, the first power stage circuit 110 and the second power stage circuit 120 are implemented with a same structure and operate according to pulse signals corresponding to input signals having different phases.

According to some embodiments, the first power stage circuit 110 and the second power stage circuit 120 may operate in a first mode that is defined to perform the above-described pull-up operation or pull-down operation according to be turned on, and may operate in a second mode in which both are turned off. For example, in the first mode, the first power stage circuit 110 and the second power stage circuit 120 may operate based on AD modulation or BD modulation.

The first power stage circuit 110 and the second power stage circuit 120 may output an effective output signal with two levels through the AD modulation and output an effective output signal with three levels through the BD modulation. When an operating voltage of the first power stage circuit 110 and the second power stage circuit 120 is VDD, an effective output signal having levels of-VDD and VDD may be output through the AD modulation, and an effective output signal having levels of-VDD, 0, and VDD may be output through the BD modulation. The BD modulation has an advantage compared to the AD modulation in that it does not require an inductor-capacitor (LC) filter for small-signal efficiency, but a common mode signal of the differential output signal may fluctuate due to modulation characteristics. Fluctuations in the common mode signal may generate electromagnetic interference (EMI) or noise in the amplifying circuit 100.

In an embodiment, the current path switch CP_SW is connected to the first node N1 and the second node N2 through which differential output signals are output. The current path switch CP_SW may be implemented with various devices or components capable of switching operations, including transistors, as long as the devices or components may open or short-circuit the first node N1 and the second node N2. According to an embodiment, the current path switch CP_SW is turned on when the first power stage circuit 110 and the second power stage circuit 120 are turned off. In an embodiment, the current path switch CP_SW is turned on in the second mode and turned off in the first mode.

In the second mode, when the BD modulation is performed, the first output signal OUT1 and the second output signal OUT2 alternately represent voltages having two levels. In this case, when the current path switch CP_SW is turned on, the current from the first power stage circuit 110 and the second power stage circuit 120 flows through a path between the first node N1 and the second node N2, which are short-circuited, and the load. In detail, the current path may be a closed loop including the load, the first node N1, and the second node N2. When the current path is formed by the current path switch CP_SW, both the first output signal OUT1 and the second output signal OUT2 may have the same voltage. Accordingly, a common mode voltage VCM may be maintained at a uniform level without changing.

In addition, since the current path switch CP_SW is connected to the first node N1 and the second node N2, the current path may be formed with a small number of switches and a small area compared to placing switches into each power stage circuit.

The voltage supply circuit 130 may be connected to the first node N1 and the second node N2 and may be configured to supply a voltage of a specific level to the first node N1 and the second node N2. According to an embodiments, the voltage supply circuit 130 is configured to supply the common mode voltage VCM associated with the first output signal OUT1 and the second output signal OUT2 to the first node N1 and the second node N2, when the first power stage circuit 110 and the second power stage circuit 120 are turned off. For example, the common mode voltage VCM may be defined as VDD/2.

The same common mode voltage VCM may be supplied to the first node N1 and the second node N2 through the voltage supply circuit 130. Accordingly, the first output signal OUT1 and the second output signal OUT2 may have a waveform that swings based on the common mode voltage VCM. In an embodiment, in the second mode, levels of the first output signal OUT1 and the second output signal OUT2 are maintained at the common mode voltage VCM.

The amplifying circuit 100 according to the above-described embodiment is implemented with a full-bridge form and may reduce EMI and noise by removing fluctuations in the common mode signal when output signals are output through BD modulation.

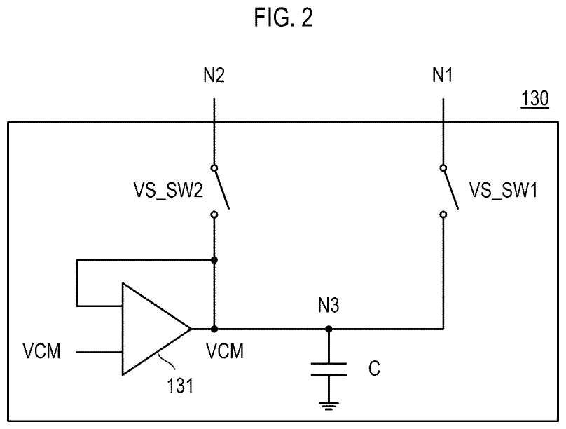

FIG. 2 is a circuit diagram of a voltage supply circuit, according to an embodiment.

Referring to FIG. 2, the voltage supply circuit 130 according to an embodiment includes a first voltage supply switch VS_SW1, a second voltage supply switch VS_SW2, a capacitor ‘C’, and a voltage follower 131. The voltage follower 131 may be a buffer amplifier or a unity-gain amplifier. The voltage follower 131 may be an electronic circuit with a gain of one. For example, the output voltage may follow or mirror the input voltage without any amplification or attenuation.

In an embodiment, the first voltage supply switch VS_SW1 is connected to the first node N1 and a third node N3, and the second voltage supply switch VS_SW2 is connected to the second node N2 and the third node N3. Like the current path switch CP_SW, the first voltage supply switch VS_SW1 and the second voltage supply switch VS_SW2 may be implemented with various devices or components capable of switching operations, including transistors, as long as the devices or components may open or short-circuit the first node N1 and the third node N3 or the second node N2 and the third node N3.

According to an embodiments, a size of the current path switch CP_SW of FIG. 1 is greater than a size of the first voltage supply switch VS_SW1 and a size of the second voltage supply switch VS_SW2. In detail, the current path switch CP_SW may be implemented as a relatively large-sized switch, and the first voltage supply switch VS_SW1 and the second voltage supply switch VS_SW2 may be implemented as relatively small-sized switches. When the current path switch CP_SW is implemented as a relatively large-sized switch, the resistance of the current path switch CP_SW is reduced, so the performance of the current path switch CP_SW forming the current path may be further increased. In an embodiment, the resistance of the current path switch CP_SW is lower than the resistance of the first voltage supply switch VS_SW1 and the second voltage supply switch VS_SW2.

According to an embodiment, the first voltage supply switch VS_SW1 and the second voltage supply switch VS_SW2 are turned on when the first power stage circuit 110 and the second power stage circuit 120 are turned off, and are turned off based when the first power stage circuit 110 and the second power stage circuit 120 are turned on. In detail, the first voltage supply switch VS_SW1 and the second voltage supply switch VS_SW2 may be turned on or off together with the current path switch CP_SW.

The capacitor ‘C’ is connected to the third node N3 and a ground to precharge a voltage formed at the third node N3.

The voltage follower 131 has an output terminal connected to the third node N3 and may provide the common mode voltage VCM to the third node N3. In an embodiment, the voltage follower 131 has a first input terminal to which the common mode voltage VCM is supplied, and has a second input terminal and an output terminal which are connected to the third node N3. The common mode voltage VCM which is output to the third node N3 through the voltage follower 131 may be supplied to the first node N1 and the second node N2 at its level when the first voltage supply switch VS_SW1 and the second voltage supply switch VS_SW2 are turned on. Accordingly, in the second mode, the voltages of the first node N1 and the second node N2 may both be the common mode voltage VCM.

The voltage supply circuit 130 according to the above-described embodiment forms a voltage path that supplies a voltage to the first node N1 and the second node N2 separately from the current path switch CP_SW of FIG. 1. Accordingly, the amplifying device of FIG. 1 may have the current path and the voltage path, which are separate from each other. Depending on the embodiment, the current path switch CP_SW has a large size, so that the current path may be formed more smoothly and a mid-level voltage of the differential output signals may be defined as the common mode voltage VCM. A differential signal consists of two complementary signals, and the mid-level voltage may refer to the common mode voltage that lies between the two signals of the differential pair. For example, the common mode voltage may be the average of the two signals.

The voltage supply circuit 130 according to the above-described embodiment may be implemented with a minimum number of switches and a minimum number of voltage followers 131. Therefore, current consumption may be reduced compared to a method of supplying a voltage through resistance dividing. Additionally, a uniform voltage may be supplied to the output node despite process-voltage-temperature (PVT) variations.

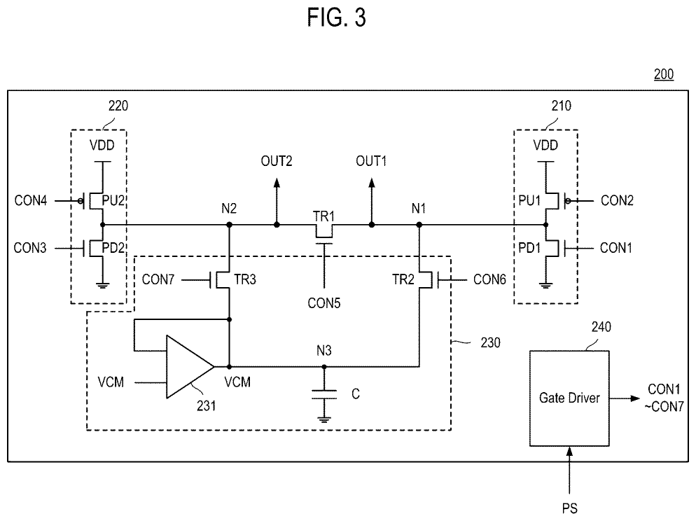

FIG. 3 is a circuit diagram of an amplifying circuit, according to an embodiment.

Referring to FIG. 3, an amplifying circuit 200 according to an embodiment further includes, in addition to the configurations of FIG. 1, a first power stage circuit 210, a second power stage circuit 220, a current path switch, and a gate driver 240 (e.g., a driver circuit) configured to control the first voltage supply switch and the second voltage supply switch.

In an embodiment, the first power stage circuit 210 includes a first inverter that outputs the first output signal OUT1 through the pull-up or the pull-down based on being turned on (i.e., in the first mode), and the second power stage circuit 220 includes a second inverter that outputs the second output signal OUT2 through the pull-up or the pull-down based on being turned on. For example, the first power stage circuit 210 outputs the first output signal OUT1 when the first power stage circuit 210 is turned on and the second power stage circuit 220 outputs the second output signal OUT2 when the second power stage circuit 220 is turned on. The first inverter may include a first pull-up transistor PU1 and a first pull-down transistor PD1, and the second inverter may include a second pull-up transistor PU2 and a second pull-down transistor PD2.

The pull-up transistors PU1 and PU2 may be implemented with a P-type Metal Oxide Semiconductor Field Effect Transistor (PMOSFET). In this case, the pull-up transistors PU1 and PU2 may have a source to which the operating voltage VDD is supplied, a gate to which a control signal from the gate driver 240 is applied, and a drain connected to an output terminal which outputs the differential output signal. In an embodiment, the first node N1 or the second node N2 are connected to the drains of the pull-up transistors PU1 and PU2. According to some embodiments, a plurality of operating voltages VDD for multi-level operation may be supplied to the sources of the pull-up transistors PU1 and PU2.

The pull-down transistors PD1 and PD2 may be implemented with an N-type Metal Oxide Semiconductor Field Effect Transistor (NMOSFET). In this case, the pull-down transistors PD1 and PD2 may have a drain connected to the first node N1 or the second node N2, which is the output terminal, a gate to which a control signal from the gate driver 240 is applied, and a source grounded.

The pull-up transistors PU1 and PU2 may perform the pull-up on the output voltage of the output terminal based on the plurality of operating voltages VDD, and the pull-down transistors PD1 and PD2 may perform the pull-down on the output voltage to the ground voltage. A pair of transistors is selected from among the pull-up transistors PU1 and PU2 and the pull-down transistors PD1 and PD2 through the control signal, and the selected pair of transistors may perform the pull-up and the pull-down depending on a duty ratio. The duty may refer to the proportion of time within a given period that a particular transistor pair is active or turned on. For example, the duty ratio may control how long the pull-up or pull-down action is applied during each cycle of an operation.

According to an embodiment, the current path switch CP_SW is implemented with a first transistor TR1, the first voltage supply switch included in a voltage supply circuit 230 is implemented with a second transistor TR2, and the second voltage supply switch may be implemented with a third transistor TR3. For example, in FIG. 3, the first transistor TR1, the second transistor TR2, and the third transistor TR3 are implemented as NMOSFETs, but embodiments of the present disclosure are not limited thereto.

The first transistor TR1 includes a drain connected to the second node N2, a gate to which a fifth control signal CON5 is supplied, and a source connected to the first node N1. The second transistor TR2 includes a drain connected to the first node N1, a gate to which a sixth control signal CON6 is supplied, and a source connected to the third node N3. The third transistor TR3 includes a drain connected to the second node N2, a gate to which a seventh control signal CON7 is supplied, and a source connected to the third node N3. The voltage supply circuit 230 may provide the common mode voltage VCM to the third node N3 through a capacitor ‘C’ connected between the third node N3 that is connected to the source of the second transistor TR2 and the source of the third transistor TR3 and the ground, and the voltage follower 231 connected to the third node N3. Accordingly, the common mode voltage VCM is supplied to the sources of the second transistor TR2 and the third transistor TR3.

The first transistor TR1, the second transistor TR2, and the third transistor TR3 may be turned on or off together based on a control signal.

According to an embodiment, a size of the first transistor TR1 is greater than sizes of the second transistor TR2 and the third transistor TR3. Accordingly, the current from the first power stage circuit 210 and the second power stage circuit 220 mainly flows through the current path formed through the first transistor TR1. In an embodiment, a resistance of the first transistor TR1 is lower than resistances of the second transistor TR2 and the third transistor TR3.

The gate driver 240 may generate a plurality of control signals CON1 to CON7 for controlling each transistor based on pulse signals generated from the differential input signals. Each control signal may be applied to a corresponding gate of each transistor. Accordingly, the gate driver 240 may control the first to third transistors TR1 to TR3, the first pull-up transistor PU1, the first pull-down transistor PD1, the second pull-up transistor PU2, and the second pull-down transistor PD2, using the plurality of control signals CON1 to CON7.

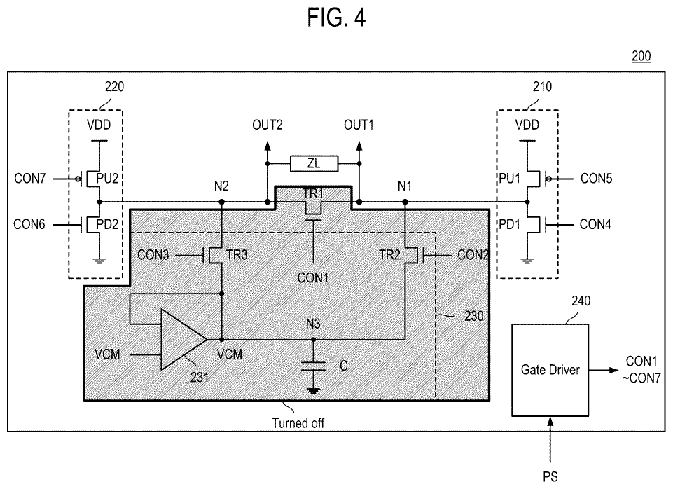

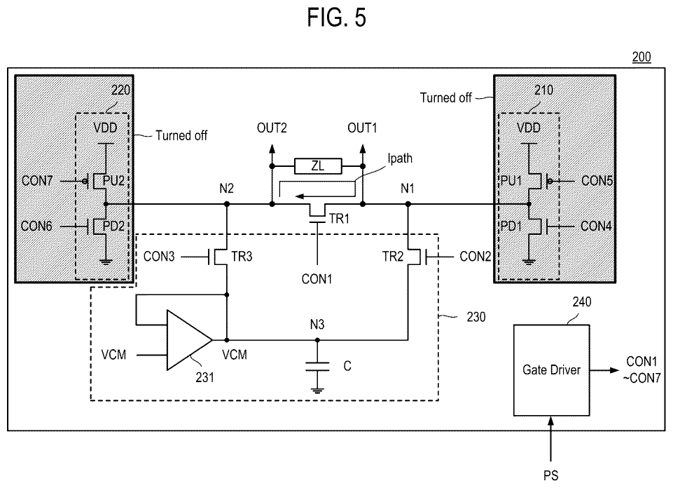

According to an embodiments, the gate driver 240 turns on the first to third transistors TR1 to TR3 when (i.e., in the second mode) the first inverter of the first power stage circuit 210 and the second inverter of the second power stage circuit 220 are turned off (i.e., based on that the first pull-up transistor PU1, the first pull-down transistor PD1, the second pull-up transistor PU2, and the second pull-down transistor PD2 are turned off). Alternatively, the gate driver 240 may turn off the first to third transistors TR1 to TR3 when (i.e., in the first mode) the first power stage circuit 210 and the second power stage circuit 220 are turned on. Hereinafter, the operation of the gate driver 240 will be described with reference to FIGS. 4 and 5.

FIG. 4 illustrates an operation of an amplifying circuit in a first mode, according to an embodiment, and FIG. 5 illustrates an operation of an amplifying circuit in a second mode, according to an embodiment.

First, referring to FIG. 4, in an embodiment of the first mode, the gate driver 240 generates the control signals CON1 to CON3 for turning off the first to third transistors TR1 to TR3, and generates the control signals CON4 to CON7 for turning on or off the first pull-up transistor PU1, the first pull-down transistor PD1, the second pull-up transistor PU2, and the second pull-down transistor PD2, based on a pulse signal. In the case of the BD modulation, all of the first pull-up transistor PU1, the first pull-down transistor PD1, the second pull-up transistor PU2, and the second pull-down transistor PD2 may be independently turned on or off. A current path is formed between the first node N1 and the second node N2 depending on the turning on or turning off of the first pull-up transistor PU1, the first pull-down transistor PD1, the second pull-up transistor PU2, and the second pull-down transistor PD2, and then the first output signal OUT1 and the second output signal OUT2 may be output to a load ZL.

Next, referring to FIG. 5, in an embodiment of the second mode, the gate driver 240 generates the control signals CON1 to CON3 for turning on the first to third transistors TR1 to TR3, and generates the control signals CON4 to CON7 for turning off all of the first pull-up transistor PU1, the first pull-down transistor PD1, the second pull-up transistor PU2, and the second pull-down transistor PD2, based on the pulse signal.

When the first transistor TR1 is turned on, the current flows through a current path Ipath including the first node N1, the second node N2, and the load ZL. Accordingly, the same voltage appears at the first node N1 and the second node N2.

On the voltage supply circuit 230 side, the common mode voltage VCM is supplied to the third node N3 and the capacitor ‘C’ through the voltage follower 231, and as the second transistor TR2 and the third transistor TR3 are turned on, the common mode voltage VCM may be supplied to the first node N1 and the second node N2. Accordingly, the first output signal OUT1 and the second output signal OUT2 that are output to the first node N1 and the second node N2 may represent a waveform that swings the common mode voltage VCM. For example, when the waveform represented by OUT1 and OUT2 causes the common mode voltage VCM to swing, it may indicate that the average voltage of these two signals is changing over time. Additionally, the common mode voltage VCM of the first output signal OUT1 and the second output signal OUT2 may be maintained at a uniform level.

The amplifying devices according to the above-described embodiments may respectively perform current path forming and voltage supplying with respect to the output node in the second mode in which each power stage circuit is turned off through the gate driver 240. Accordingly, fluctuations in the common mode voltage VCM may be resolved and EMI and noise may be reduced.

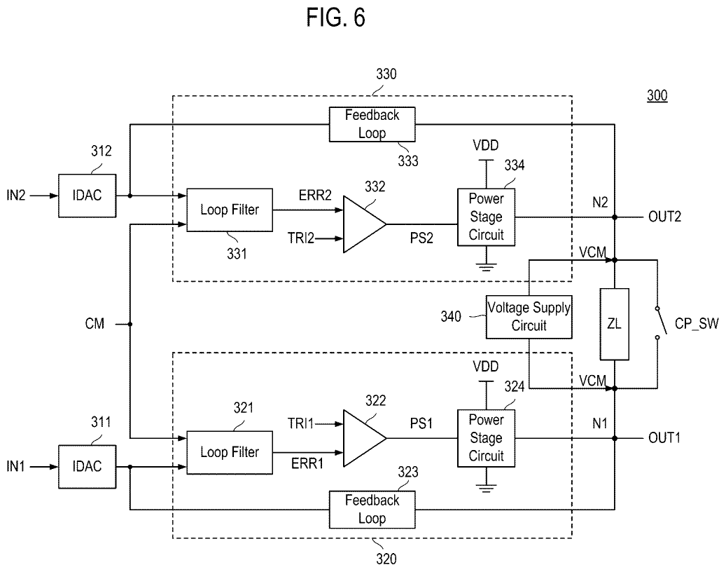

FIG. 6 illustrates an amplifying device, according to an embodiment. Hereinafter, additional descriptions of overlapping contents with the above contents will be omitted to avoid redundancy.

Referring to FIG. 6, an amplifying device according to an embodiment includes a pair of current digital-to-analog converters (DACs) 311 and 312, a pair of amplifying channels 320 and 330, the current path switch CP_SW, and a voltage supply circuit 340.

The pair of current DACs 311 and 312 are connected to input terminals of a pair of loop filters 321 and 331 included in the pair of amplifying channels 320 and 330, and may convert differential input signals IN1 and IN2, which are digital signals to analog signals (e.g., analog differential input signal). As a result of the conversion, an analog current may be supplied to the pair of loop filters 321 and 331.

The pair of amplifying channels 320 and 330 may be configured to generate differential pulse signals PS1 and PS2 from the differential input signals IN1 and IN2, a common mode signal CM, and differential triangle wave signals TRIL and TRI2, and to output the differential output signals OUT1 and OUT2 corresponding to the differential pulse signals PS1 and PS2, based on the operating voltage VDD and a ground voltage.

The pair of amplifying channels 320 and 330 may include the first amplifying channel 320 and the second amplifying channel 330, which are connected to the load ZL. According to an embodiment, the first amplifying channel 320 is configured in a same way as the second amplifying channel 330. However, when the signals associated with the first amplifying channel 320 correspond to one signal of the pair of differential signals, the signals associated with the second amplifying channel 330 may correspond to the remaining signal. In an embodiment, the signals associated with the first amplifying channel 320 and the signals associated with the second amplifying channel 330 have different phases.

According to an embodiment, the pair of amplifying channels 320 and 330 include the pair of loop filters 321 and 331, a pair of comparators 322 and 332, a pair of feedback loops 323 and 333 (e.g., feedback loop circuits), and a pair of power stage circuits 324 and 334. The pair of current DACs 311 and 312 may be replaced with other components capable of DAC converting.

The pair of loop filters 321 and 331 may be configured to output differential error signals ERR1 and ERR2 by filtering the feedback signals based the differential input signals. A signal corresponding to a difference between one input signal and one fed-back signal and the common mode signal CM may be applied to each of the pair of loop filters 321 and 331. In an embodiment, the differential error signals ERR1 and ERR2 are sine waves and are each output as a signal that swings the common mode voltage VCM corresponding to the common mode signal CM.

According to an embodiment, each of the pair of loop filters 321 and 331 is implemented as a higher-order filter to increase filtering performance. According to some embodiments, each of the pair of loop filters 321 and 331 may be composed of one or more integrators. For example, the higher-order filter may refer to a filter of order greater than two.

The pair of comparators 322 and 332 may generate the differential pulse signals PS1 and PS2 by comparing the differential error signals ERR1 and ERR2 with the differential triangle wave signals TRI1 and TRI2. As an example, the first comparator 322 may output the first pulse signal PS1 based on the first error signal ERR1 compared with the first triangle wave signal TRI1.

The pair of feedback loops 323 and 333 may be configured to be connected to the input terminals of the pair of loop filters 321 and 331, and the first node N1 and the second node N2 through which the differential output signals OUT1 and OUT2 are output, and may be configured to provide fed back signals to the input terminals of the pair of loop filters 321 and 331. As an example, the first feedback loop 323 may be connected to the input terminal of the first loop filter 321 and the first node N1 through which the first output signal OUT1 is output.

The pair of power stage circuits 324 and 334 may be configured to output the differential output signals OUT1 and OUT2 to the load (e.g., ZL) connected to the first node N1 and the second node N2 through the pull-up or the pull-down, based on the differential pulse signals PS1 and PS2. As an example, the first power stage circuit 324 may output the first output signal OUT1 through the pull-up or the pull-down, based on the first pulse signal PS1. In an embodiment, the first output signal OUT1 has a polarity opposite to that of the first input signal IN1. Likewise, the second output signal OUT2 may have a polarity opposite to that of the second input signal IN2.

The current path switch CP_SW and the voltage supply circuit 340 according to the above-described embodiment is connected to the first node N1 and the second node N2 to which the load ZL is connected. When the pair of power stage circuits 324 and 334 are turned off and the current path switch CP_SW is turned on, the current path switch CP_SW may form a current path. In addition, the voltage supply circuit 340 may supply the common mode voltage VCM corresponding to the voltage of the common mode signal CM with respect to the differential output signals OUT1 and OUT2 to the first node N1 and the second node N2 when the pair of power stage circuits 324 and 334 are turned off. For example, the common mode voltage VCM may be one-half the operating voltage VDD.

Accordingly, even if the pair of power stage circuits 324 and 334 operate according to BD modulation, the common mode voltages VCM may be maintained at a same level. In this case, the first output signal OUT1 and the second output signal OUT2 may represent a waveform that swings based on the common mode voltage VCM.

According to an embodiment, the pair of current DACs 311 and 312 may need the common mode voltage VCM to be stable. When the common mode voltage VCM fluctuates, the fluctuating common mode voltage VCM may be fed back through the pair of feedback loops 323 and 333. Therefore, to respond to the fluctuating common mode voltage VCM, a programmable gain amplifier (PGA) may be added between the pair of current DACs 311 and 312 and the input terminals. In this case, the output signals of the pair of current DACs 311 and 312 are converted into voltage signals through the PGAs, and input resistors may be additionally used to apply the voltage signal to the input terminals. Due to additional components such as the PGAs and the input resistors, noise in the amplifying device may increase.

In contrast, an amplifying device 300 according to the above-described embodiment is capable of maintaining the common mode voltage VCM at a specific level through the current path switch CP_SW and the voltage supply circuit 340, so that the pair of current DACs 311 and 312 may be directly connected to the input terminals. In this way, the amplifying device 300 may generate less noise and have higher a DR dynamic range (DR) compared to other embodiments that are connected to other components such as the PGA.

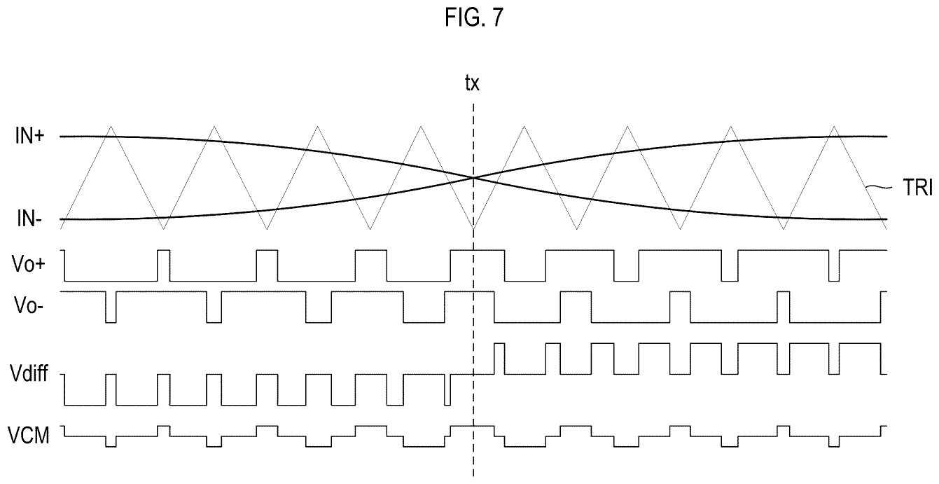

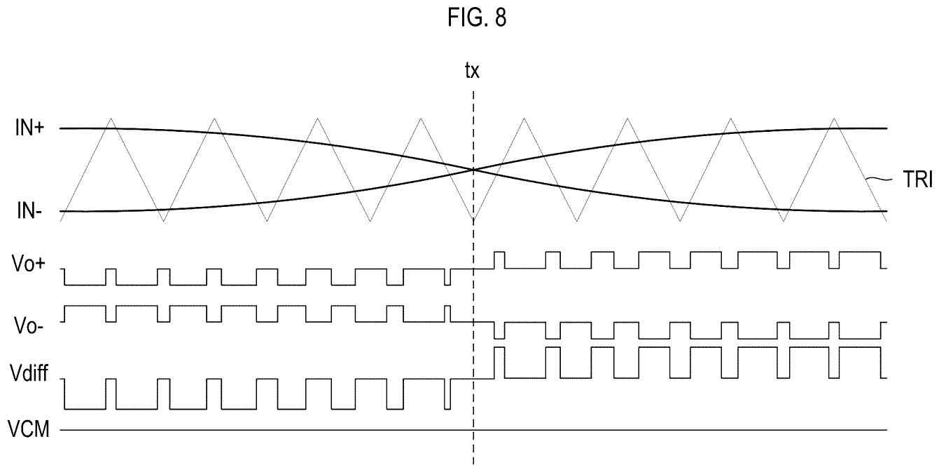

FIGS. 7 and 8 illustrate operating waveforms of the amplifying device of FIG. 6, according to some embodiments. In common, it is assumed that differential input signals have levels that fluctuate and then reverse each other with respect to a triangle wave signal. In addition, FIG. 7 illustrates operating waveforms when the current path switch and the voltage supply switch are not provided or do not operate in the amplifying device of FIG. 6.

Referring to FIG. 7, according to an embodiments, the amplifying device outputs an output signal Vo+ by comparing the triangle wave signal TR1 with the first input signal IN−, and outputs an output signal Vo− by comparing the triangle wave signal TR1 with the second input signal IN+.

An effective output signal Vdiff is output as a waveform corresponding to the difference between the output signal Vo+ and the output signal Vo−. In BD modulation, the effective output signal Vdiff has three levels as illustrated, and the level of the effective output signal Vdiff also changes after time ‘tx’ when the levels of the differential input signals are reversed. In FIG. 7, the output signal Vo+ and the output signal Vo− have two levels, and the common mode voltage VCM continuously changes in the BD modulation as illustrated in FIG. 7.

In contrast, in the case of FIG. 8, the common mode voltage VCM does not change and has the same level according to the above-described embodiment. The output signal Vo+ and output signal Vo− have a total of three levels with the common mode voltage VCM as a middle level among the three levels. Accordingly, the pulse width of the effective output signal Vdiff becomes the same as the pulse widths of the output signal Vo+ and the output signal Vo−.

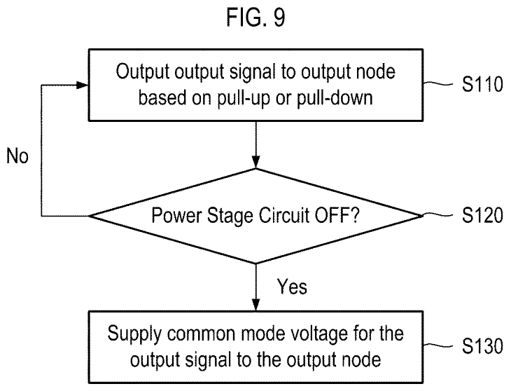

FIG. 9 is a flowchart illustrating a method of operating an amplifying device, according to an embodiments.

Referring to FIG. 9, in operation S110, the amplifying device outputs an output signal to the output node based on the pull-up or the pull-down. In operation S120, the amplifying device determines whether the power stage circuit is turned off. When the power stage circuit is off, in operation S130, the amplifying device supplies the common mode voltage for the output signal to the output node. When the power stage circuit is on, the amplifying device may repeat operation S110.

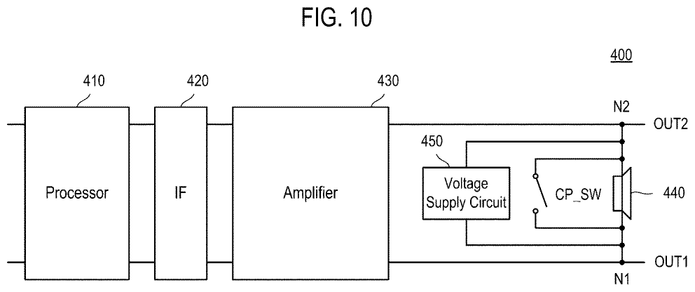

FIG. 10 illustrates an audio device, according to an embodiment.

Referring to FIG. 10, an audio device 400 according to an embodiment includes a processor 410, an interface 420 (e.g., an interface circuit), an amplifier 430, and an audio output device 440 (e.g., a speaker).

The processor 410 may perform various processing on digital audio signals. For example, the processor 410 may perform sampling rate change, filter application, interpolation processing, amplification or attenuation of a frequency band, noise processing, channel change, mixing, extraction of a specified signal, etc. on the digital audio signals.

The interface 420 may include an analog-to-digital converter (ADC) and/or a digital-to-analog converter (DAC). The interface 420 may convert a digital audio signal into an analog audio signal, or may convert an analog audio signal into a digital audio signal. According to an embodiment, the interface 420 includes the current DAC of FIG. 6 described above.

The amplifier 430 may receive the analog audio signal as an input signal from the interface 420, may amplify the input signal to generate an output signal, and may output the output signal through the first node N1 and the second node N2. The amplifier 430 may be implemented including the amplifying circuit and the amplifying device according to the above-described embodiments (e.g., FIGS. 1 to 9), or may be configured to perform the functions of the amplifying circuit and the amplifying device. According to an embodiment, the amplifier 430 generates a pulse signal by comparing a triangle wave signal with an input signal, and outputs the output signals OUT1 and OUT2 through the pull-up or the pull-down based on the pulse signal.

The audio output device 440 may be implemented as a speaker that outputs sound depending on the output signals OUT1 and OUT2 output from the amplifier 430. Alternatively, the audio output device 440 may include a receiver that receives sound. Alternatively, the audio output device 440 may include a plurality of speakers and may output sound through a plurality of different channels.

According to an embodiment, the first node N1 and the second node N2, which are both ends of the audio output device, are connected to the current path switch CP_SW and a voltage supply circuit 450 according to the above-described embodiments. The current path switch CP_SW and the voltage supply circuit 450 may operate to supply the common mode voltage VCM at a uniform level to both ends of the audio output device, thereby reducing EMI and noise of the audio device 400.

According to an embodiment of the present disclosure, an amplifying circuit and an amplifying device capable of providing a uniform common mode voltage may be provided.

The above descriptions are specific embodiments for carrying out the present disclosure. Embodiments in which the design is slightly changed are supported by the present disclosure as well as an embodiment described above. In addition, technologies that are easily changed and implemented by using the above embodiments may be included in the present disclosure. While the present disclosure has been described with reference to embodiments thereof, it will be apparent to those of ordinary skill in the art that various changes and modifications May be made thereto without departing from the spirit and scope of the present disclosure as set forth in the following claims.

What is claimed is:

1. An amplifying circuit comprising:
a first power stage circuit configured to output a first output signal to a first node based on a pull-up or a pull-down;
a second power stage circuit configured to output a second output signal to a second node based on the pull-up or the pull-down;
a current path switch connected to the first node and the second node, and configured to be turned on when the first power stage circuit and the second power stage circuit are turned off; and
a voltage supply circuit configured to supply a common mode voltage for the first output signal and the second output signal to the first node and the second node based when the first power stage circuit and the second power stage circuit are turned off.

2. The amplifying circuit of claim 1, wherein the first output signal and the second output signal are differential signals.

3. The amplifying circuit of claim 1, wherein the first power stage circuit comprises:
a first inverter configured to output the first output signal through the pull-up or the pull-down based on being turned on, and
wherein the second power stage circuit comprises:
a second inverter configured to output the second output signal through the pull-up or the pull-down based on being turned on.

4. The amplifying circuit of claim 1, wherein the voltage supply circuit comprises:
a first voltage supply switch connected to the first node and a third node;
a second voltage supply switch connected to the second node and the third node;
a capacitor connected to the third node and a ground; and
a voltage follower connected to the third node and configured to provide the common mode voltage to the third node.

5. The amplifying circuit of claim 4, wherein the first voltage supply switch and the second voltage supply switch are turned on when the first power stage circuit and the second power stage circuit are turned off.

6. The amplifying circuit of claim 4, wherein a size of the current path switch is greater than a size of the first voltage supply switch and a size of the second voltage supply switch.

7. The amplifying circuit of claim 4, wherein the voltage follower includes an amplifier including a first input terminal receiving the common mode voltage, and a second input terminal and an output terminal connected to the third node.

8. The amplifying circuit of claim 1, wherein the common mode voltage is half is an operating voltage of the first power stage circuit and the second power stage circuit.

9. The amplifying circuit of claim 4, further comprising:
a gate driver configured to control the first power stage circuit, the second power stage circuit, the current path switch, the first voltage supply switch, and the second voltage supply switch.

10. The amplifying circuit of claim 9, wherein the gate driver is configured to:
turn on the current path switch, the first voltage supply switch, and the second voltage supply switch when the first power stage circuit and the second power stage circuit are turned off; and
turn off the current path switch, the first voltage supply switch, and the second voltage supply switch when the first power stage circuit and the second power stage circuit are turned on.

11. An amplifying circuit comprising:
a first inverter configured to output a first output signal to a first node based on a pull-up or a pull-down;
a second inverter configured to output a second output signal to a second node based on the pull-up or the pull-down;
a first transistor connected between the first node and the second node, and configured to be turned on when the first inverter and the second inverter are turned off;
a second transistor connected between the first node and a common mode voltage, and configured to be turned on when the first inverter and the second inverter are turned off; and
a third transistor connected between the second node and the common mode voltage, and configured to be turned on when the first inverter and the second inverter are turned off.

12. The amplifying circuit of claim 11, further comprising:
a capacitor connected to a third node which is connected to a source of the second transistor and the source of the third transistor and connected to a ground; and
a voltage follower connected to the third node and configured to provide the common mode voltage to the third node.

13. The amplifying circuit of claim 11, wherein the first inverter comprises:
a first pull-up transistor connected between an operating voltage and the first node; and
a first pull-down transistor connected between the first node and a ground,
wherein the second inverter comprises:
a second pull-up transistor connected between the operating voltage and the second node; and
a second pull-down transistor connected between the second node and a ground.

14. The amplifying circuit of claim 11, wherein a size of the first transistor is greater than a size of the second transistor and a size of the third transistor.

15. The amplifying circuit of claim 11, wherein the common mode voltage is half an operating voltage of the first inverter and the second inverter.

16. The amplifying circuit of claim 13, further comprising:
a gate driver configured to control the first to third transistors, the first pull-up transistor, the first pull-down transistor, the second pull-up transistor, and the second pull-down transistor.

17. The amplifying circuit of claim 16, wherein the gate driver is configured to,
turn on the first transistor, the second transistor, and the third transistor when the first pull-up transistor, the first pull-down transistor, the second pull-up transistor, and the second pull-down transistor are turned off.

18. An amplifying device comprising:
a pair of current digital-to-analog converters (DACs) configured to convert digital differential input signals to analog differential input signals;
a pair of amplifying channels connected to the pair of current DACs, configured to generate differential pulse signals from the analog differential input signals, a common mode signal, and differential triangle wave signals, and configured to output differential output signals corresponding to the differential pulse signals through a pair of power stage circuits;
a current path switch connected to a first node and a second node through which the differential output signals are output, and configured to be turned on when the pair of power stage circuits are turned off; and
a voltage supply circuit configured to supply a common mode voltage with respect to the differential output signals to the first node and the second node when the pair of power stage circuits are turned off.

19. The amplifying device of claim 18, wherein the common mode voltage is half an operating voltage of the pair of power stage circuits.

20. The amplifying device of claim 18, wherein the voltage supply circuit comprises:
a first voltage supply switch connected to the first node and a third node;
a second voltage supply switch connected to the second node and the third node;
a capacitor connected to the third node and a ground; and
a voltage follower connected to the third node and configured to provide the common mode voltage to the third node.
